(19) United States
(12) Patent Application Publication
(10) Pub. No.: US 2007/0290890 A1
(43) Pub. Date: Dec. 20, 2007

(54) FOLDABLE KEYBOARD

(75) Inventors: Ji-Huang Chen, Taoyuan County (TW); Shuo-Hsiu Chang, Taipei County (TW)

Correspondence Address: QUINTERO LAW OFFICE, PC, 2210 MAIN STREET, SUITE 200, SANTA MONICA, CA, 90405, US

(73) Assignee: DARFON ELECTRONICS CORP., TAOYUAN (TW)

(21) Appl. No.: 11/756,566

(22) Filed: May 31, 2007

(30) Foreign Application Priority Data
Jun. 6, 2006 (TW) TW95120004
Aug. 25, 2006 (TW) TW95131323

(51) Int. Cl. H03M 11/00; H03K 17/94

(52) U.S. Cl. 341/22

(57) ABSTRACT

A foldable keyboard is provided. The foldable keyboard includes a first module, a second module and a first pivot. The first module has a first side and a second side. The second module has a third side and a fourth side. The first pivot connects the first and second modules, whereby the first module is rotatable relative to the second module. The first side is parallel to the third side. The first side is longer than the second side. The third side is longer than the fourth side.

### BACKGROUND OF THE INVENTION

1. Field of the Invention

The invention relates to a foldable keyboard, and in particular to a foldable keyboard comprising a plurality of modules.

2. Description of the Related Art

A conventional keyboard has several rows of keys and several hot keys for multimedia usage. The conventional keyboard occupies considerable space; often taking up valuable desk space. It is impossible to use a conventional keyboard's hot keys to control multimedia items; such as those located in a living room or other places, without the inconvenience of carrying around the whole keyboard. The foldable keyboard invention offers the convenience of a smaller size and multimedia hot key usage.

### BRIEF SUMMARY OF INVENTION

A foldable keyboard is provided in the invention. An exemplary embodiment of the foldable keyboard comprises a first module, a second module and a first pivot. The first module has a first side and a second side. The second module has a third side and a fourth side. The first pivot connects the first and second modules, whereby the first module is rotatable relative to the second module. The first side is parallel to the third side. The first side is longer than the second side. The third side is longer than the fourth side.

The foldable keyboard comprises a casing slidably connected to the first module comprising of a plurality of keys, wherein the keys are revealed or partly hidden in the casing.

The first module further comprises of grooves and the casing comprises a protrusion which slidably engages the groove. The casing further comprises of multimedia usage keys.

The first module has a lower housing and a shielding element disposed on the lower casing, the second module has a lower housing and a shielding element disposed on the lower casing, the lower casings and the shielding elements of the first and second modules shield a flexible circuit board connecting the first and second modules.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a perspective exploded view of a foldable keyboard of the invention;

FIG. 2 is a perspective view of a foldable keyboard of the invention which is in a straightened position;

FIG. 3 is a perspective view of a foldable keyboard of the invention which is folded;

FIG. 4 is a side view of FIG. 2;

FIGS. 5a and 5b are enlarged cross sections of area A of FIG. 4, wherein FIG. 5a depicts the first module and the second module in straightened position, and FIG. 5b depicts the first module and the second module in a folded position;

FIG. 6 depicts another embodiment of a foldable keyboard of the invention in a straightened position; and

FIG. 7 depicts another embodiment of a foldable keyboard of the invention in a folded position.

### DETAILED DESCRIPTION OF INVENTION

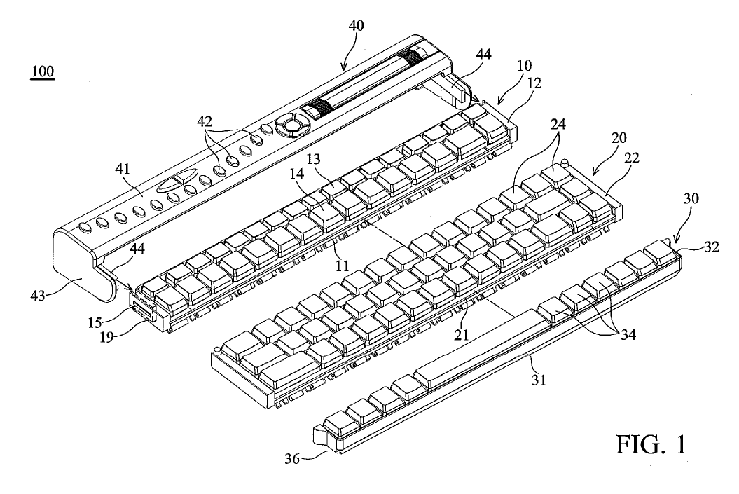

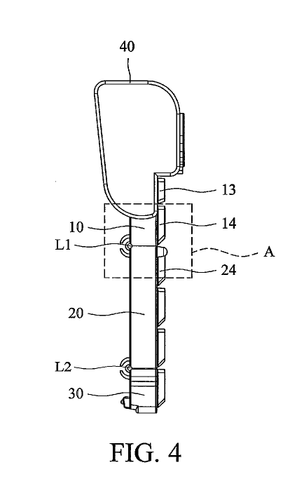

Referring to FIG. 1, a foldable keyboard 100 comprises a first module 10, a second module 20, a third module 30 and a casing 40. Referring to FIG. 4, a foldable keyboard 100 also comprises of a first shaft (first pivot) L1 and a second shaft (second pivot) L2. The first module 10 and the second module 20 are rotatable and connected to the first shaft L1. The second module 20 and the third module 30 are rotatable and connected to the second shaft L2. Referring to FIG. 1, the casing 40 is U-shaped and has a main body 41 and two walls 43. The main body 41 is rectangular. The walls 43 are connected to two lateral sides of the main body 41. First protrusions 44 project from inner side of the walls 43 and correspond to grooves 19 disposed on the lateral sides of the first module 10. The first protrusions 44 engage the grooves 19, whereby the first module 10 is slidably connected to the casing 40. The first module 10 is slid into the casing 40 for folding. A protrusion (not shown) projecting from the inner side of the casing 40, slidably engages a grooves 15 formed on the lateral sides of the first module 10, whereby the first module 10 is constrained in position when the first module 10 completely enters the casing 40.

The first module 10 is rectangular and has a first side 11, a second side 12, a plurality of first keys 13 and a plurality of second keys 14. The first side 11 is longer than the second side 12. The second module 20 is rectangular and has a third side 21, a fourth side 22 and third keys 24. The third side 21 is longer than the fourth side 22. The third module 30 is rectangular and has a fifth side 31, a sixth side 32 and a plurality of sixth keys 34. The fifth side 31 is longer than the sixth side 32. The first side 11, the third side 21 and the fifth side 31 are parallel. The casing 40 has a plurality of hot keys 42 for multimedia usage.

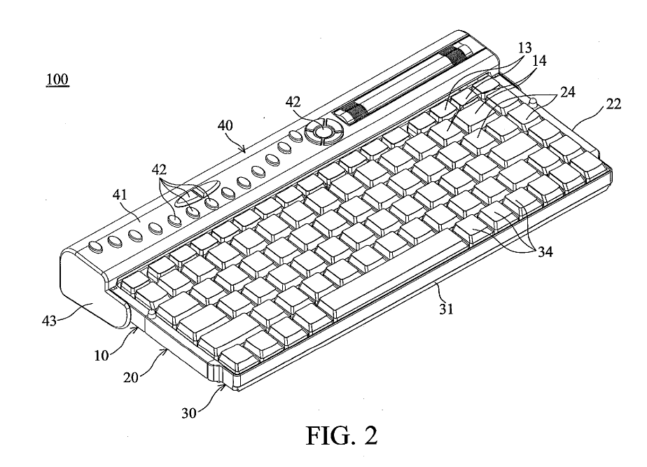

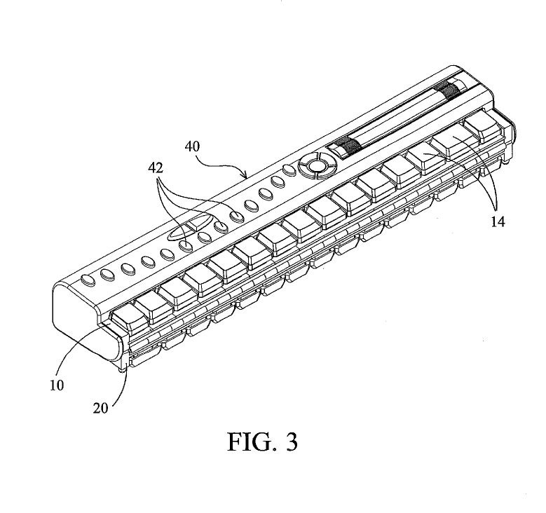

Referring to FIG. 2, when the foldable keyboard 100 is in a straightened position, the keys on the foldable keyboard 100 can be used to input data. When the foldable keyboard 100 is folded, as shown in FIG. 3, the second module 20 and the third module 30 are fully accommodated in the casing 40 with a part of the first module 10 revealed. In FIG. 3, only the second row of keys 14 is revealed. The hot keys 42 can be operated when the foldable keyboard 100 is in its folded position.

Referring to FIG. 4, when the foldable keyboard 100 is folded, the third module 30 is rotated under the second module 20 via the second shaft L2 and folded parallel to the second module 20. The second module 20 along with the third module 30 is rotated under the first module 10 via the first shaft L1 and folded parallel to the first module 10. The folded first module 10, second module 20 and third module 30 are moved into the casing 40. Referring to FIG. 1, a second groove 36 formed on the lateral sides of the third module 30 engages a second protrusion (not shown) to position the first, second and third modules 10, and 30 in the casing 40.

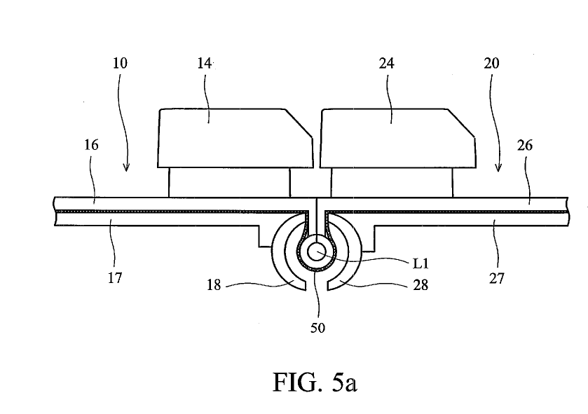

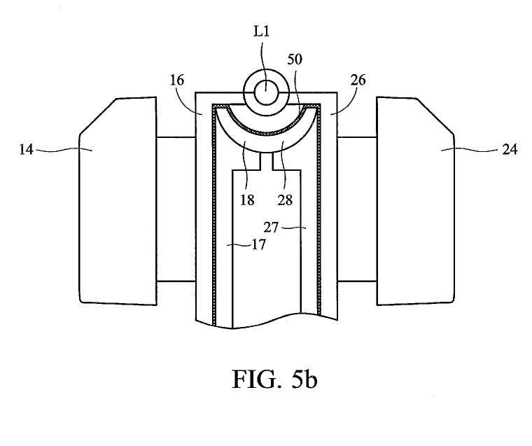

Referring to FIGS. 5a and 5b, the first module 10 comprises an upper housing 16 and a lower housing 17. The second module 20 comprises an upper housing 26 and a lower housing 27. A flexible circuit board 50 is disposed between the upper housing 16 and the lower housing 17 and between the upper housing 26 and the lower housing 27. The flexible circuit 50 extends from the first module 10 to the second module 20 via the first shaft L1. Flexible circuit board shielding elements 18 and 28 are disposed on the lower housing 17 and 27, respectively. The shielding elements 18 and 28 are curved and extend from the lower housings 17 and 27 to surround the flexible circuit board 50. As the shielding elements 18 and 28 are alternatively positioned, when the first module 10 is rotated parallel to the second module 20, the shielding element 18 and 28 will continue to shield the flexible circuit board as shown in FIG. 5b.

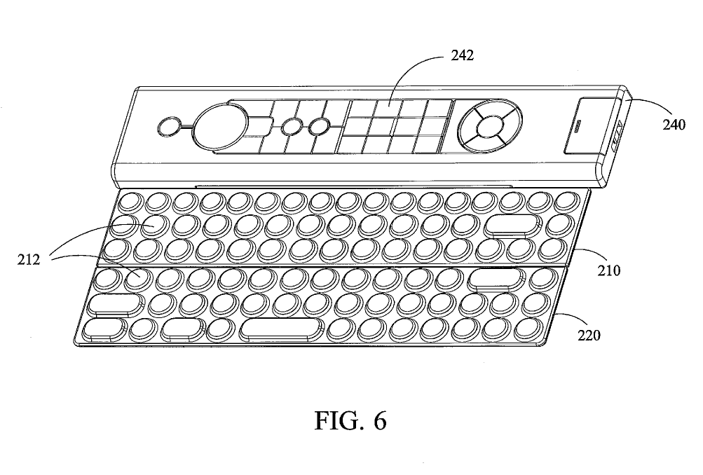

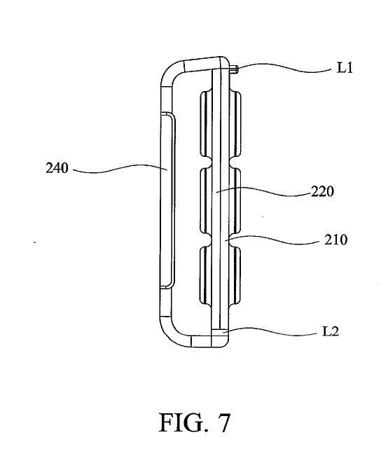

Referring to FIG. 6, another embodiment of the foldable keyboard is shown. The foldable keyboard 200 comprises a first module 210, a second module 220, a casing 240, a first shaft (first pivot) L1 and a second shaft (second pivot) L2. The casing 240 is U-shaped and capable of accommodating the first and second modules 210 and 220. The casing 240 further comprises a plurality of multimedia keys 242. The first module 210 is pivoted to the casing 240 by the first shaft L1. The second module 220 is pivoted to the first module 210 by the second shaft L2. The first module 210 and the second module 220 have a plurality of keys 212. In FIG. 7, when the first module 210 and the second module 220 are in the folded position, they can be accommodated in the casing 240.

In addition to data input, the foldable keyboard can be used to operate multimedia products when folded. If the foldable keyboard is wireless type, it can serve as a remote control; like those used in a living room or other places.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A foldable keyboard comprising:
a first module having a first side and a second side;
a second module having a third side and a fourth side;
a first pivot connecting the first and second modules, whereby the first module is rotatable relative to the second module, wherein the first side is substantially parallel to the third side, the first side is longer than the second side, and the third side is longer than the fourth side.

2. The foldable keyboard as claimed in claim 1 further comprises a casing slidably or rotatably connected to the first module comprising of a plurality of keys.

3. The foldable keyboard as claimed in claim 2, wherein when the first module is rotated relatively to the second module to a folded position, the folded first and second modules are accommodated in the casing.

4. The foldable keyboard as claimed in claim 2, wherein the first module further comprises a groove and the casing comprises a protrusion which slidably engages the grooves.

5. The foldable keyboard as claimed in claim 2, wherein the casing further comprises of multimedia keys.

6. The foldable keyboard as claimed in claim 1, wherein the first side is substantially as long as the third side.

7. The foldable keyboard as claimed in claim 1, wherein the first module has a lower housing and a shielding element disposed on the lower casing, the second module has a lower housing and a shielding element disposed on the lower casing, the lower casings and the shielding elements of the first and second modules shield a flexible circuit board connecting the first and second modules.

8. A foldable keyboard, comprising:
a first module having a first side and a second side;
a second module having a third side and a fourth side;
a third module having a fifth side and a sixth side;
a first pivot connecting the first and second modules, whereby the first module is rotated relative to the second module;
a second pivot connecting the second and third modules, whereby the second module is rotated relative to the third module, wherein the first side is parallel to the third side and the fifth side, the first side is longer than the second side, the third side is longer than the fourth side, and the fifth side is longer than the sixth side.

9. The foldable keyboard as claimed in claim 8 further comprises a casing slidably or rotatably connected to the first module comprising of a plurality of keys.

10. The foldable keyboard as claimed in claim 9, wherein when the second module is rotated relatively to the first module and the third module to a folded position, the folded first, second and third modules are accommodated in the casing.

11. The foldable keyboard as claimed in claim 8, wherein the fourth side of the second module has a length equal to the summation of the lengths of the second side of the first module and sixth side of the third module.

12. The foldable keyboard as claimed in claim 8, wherein the first module further comprises a groove and the casing comprises a protrusion which slidably engages the groove.

13. The foldable keyboard as claimed in claim 9, wherein the first side, the third side and the fifth side have the same length.

14. The foldable keyboard as claimed in claim 8, wherein the first module has a lower housing and a shielding element disposed on the lower casing, the second module has a lower housing and a shielding element disposed on the lower casing, the lower casings and the shielding elements of the first and second modules shield a flexible circuit board connecting the first and second modules.
